(19) United States
(12) Patent Application Publication
(10) Pub. No.: US 2012/0068043 A1
(43) Pub. Date: Mar. 22, 2012

(54) PERSONAL ELECTRONIC DEVICE HOLDER SYSTEMS

(75) Inventors: Jamie Daigle, Portland, OR (US); Bryan Churchill, Durham, OR (US); Toren Orzeck, Portland, OR (US); Evon E. Epling, Portland, OR (US); Ross D. Savage, Portland, OR (US)

(73) Assignee: DC MOBILE DESIGN, LLC, Portland, OR (US)

(21) Appl. No.: 13/187,494

(22) Filed: Jul. 20, 2011

Related U.S. Application Data
(60) Provisional application No. 61/400,011, filed on Jul. 20, 2010.

(51) Int. Cl. H05K 7/00

(52) U.S. Cl. 248/682

(57) ABSTRACT

An assembly for facilitating holding an electronic device, such as a tablet, or the like comprising a cover for detachably receiving and holding the electronic device and a handle mounted on the cover and rotatable about an axis generally perpendicular to the plane of the back of the electronic device.

### CROSS-REFERENCE TO RELATED PATENTS

This application claims priority of U.S. Provisional Patent Application Ser. No. 61/400,011, which is incorporated herein by reference in its entirety for all purposes. This application also incorporates by reference the complete disclosures of U.S. Design Pat. No. D515,082 and U.S. Patent Application Publication No. 2009/0127309 for all purposes.

### BACKGROUND OF THE DISCLOSURE

Personal electronic devices, such as tablet computers and electronic books (e-books), provide a user the convenience of having a computer in a single component, such as a flat touch screen. In some personal electronic devices, a stylus or fingertip may be used as an input device of the electronic device. The personal electronic device typically is smaller than a laptop computer or personal computer so a user typically will hold the device closer to his or her face as compared to those computers.

The weight of the personal electronic device may, however, prevent the user from using that device for extended periods of time. A user may support his or her holding arm against a support surface or another part of the body to enable the user to use the device for an extended period of time. Alternatively, one or more holders may be used for the personal electronic device.

### BRIEF DESCRIPTION OF THE DRAWINGS

FIG. 1 is a schematic view of an example of a personal electronic device holder system for a personal electronic device.

FIGS. 2-5 are sketches showing examples of a holder assembly of the personal electronic device holder system of FIG. 1.

FIGS. 6-24 are photographs showing an example of the personal electronic device holder system of FIG. 1.

FIGS. 25-34 are sketches showing other examples of the personal electronic device holder system of FIG. 1.

FIG. 35 is a perspective view of the holder assembly, including a handle assembly mounted on a cover, which in turn is mounted on an electronic device such as an iPad or other tablet.

FIG. 36 is a view of the holder assembly of FIG. 35, viewed from above.

FIG. 37 is a view showing a hand gripping the handle of the holder assembly, with the fingers wrapped around the handle and the palm and inside of the fingers generally facing the back of the cover.

FIG. 38 is a schematic top plan view of the holder assembly, illustrating the handle positioned in the central mount, four auxiliary mounts also being illustrated.

FIG. 39 is a side view of the arrangement shown in FIG. 38 with the handle resting on a surface orienting the tablet in the “point and tap” position.

FIG. 40 is a view similar to FIG. 38 with the handle positioned in an auxiliary mount located on one side of the cover.

FIG. 41 is a side view of the arrangement shown in FIG. 40 with the handle resting on a surface orienting the tablet in a viewing position.

FIG. 42 is a view similar to FIGS. 38 and 40 with the handle positioned in an auxiliary mount provided on one of the shorter sides of the cover.

FIG. 43 is a side view of the arrangement shown in FIG. 42 with the handle resting on a surface orienting the tablet in a typing position.

FIG. 44 is a perspective view of a handle, with open ends, showing the releasable locking assembly.

FIG. 44A is an enlarged view of the releasable locking assembly of FIG. 44.

FIG. 45 is an exploded view, with portions cut away, showing the central rotatable mount in relation to the cover of the holder assembly.

FIG. 46 is an enlarged view, in cross section, of the releasable locking assembly on the handle in locked position on the cover.

FIG. 47 is a side cross sectional view, showing the handle and its releasable locking assembly positioned in the central rotatable mount.

FIG. 48 is a cross sectional view similar to FIG. 47, showing the handle and its releasable locking assembly positioned in an auxiliary mount.

FIG. 49 is an enlarged view, with portions broken away, of the releasable locking assembly of the handle shown in its normally biased extended position for locking in the central rotatable mount or one of the auxiliary mounts.

FIGS. 49A and 49B are broken away views, shown in perspective, of portions of the releasable locking assembly.

FIG. 49C is an enlarged view showing the torsion spring employed in the releasable locking assembly.

FIG. 50 is a view similar to FIG. 49 showing cam action to retract the locking members or “strikers” so that the handle may be removed or inserted in the central rotatable mount or a selected one of the auxiliary mounts.

FIGS. 51 and 52 are views, shown in perspective of the same action shown in FIGS. 49 and 50, respectively.

FIG. 53 is an enlarged view of the handle, separated from the cover showing cap trays in their detached position from the handle.

### DETAILED DESCRIPTION OF THE DISCLOSURE

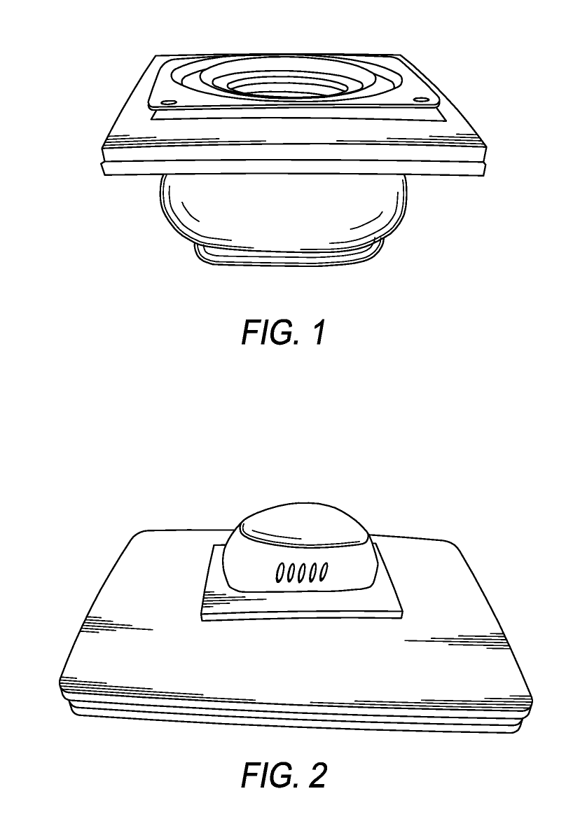

FIG. 1 shows some embodiments of a personal electronic device holder system for one or more personal electronic devices. The holder system may include a holder assembly and a handle assembly. The holder assembly may include any suitable structure configured to attach to and/or support one or more portions of the personal electronic device(s).

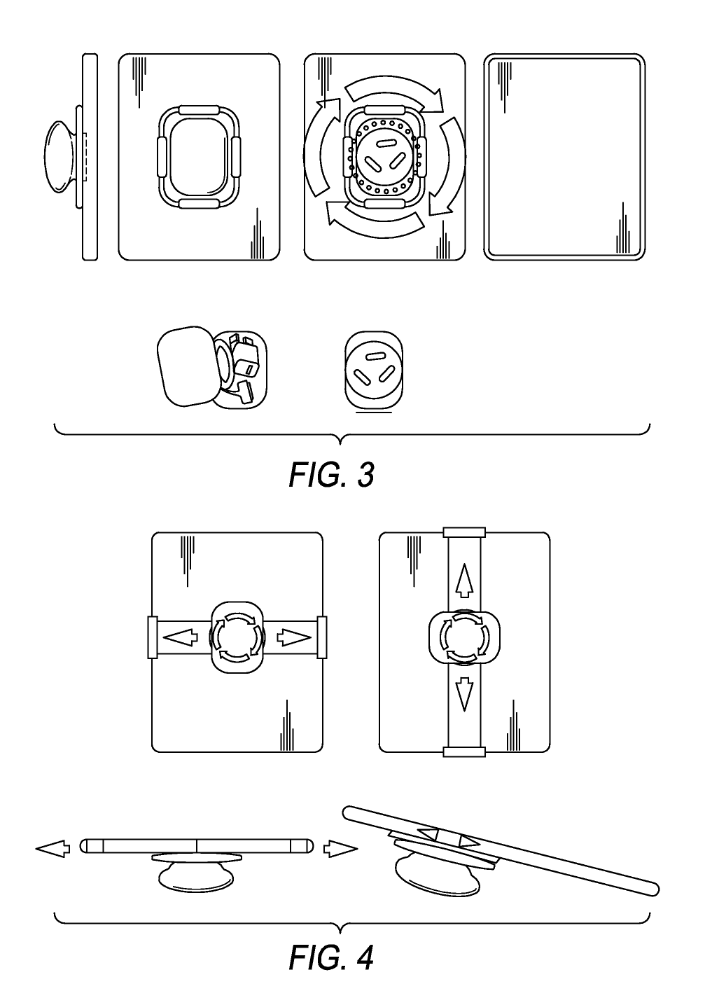

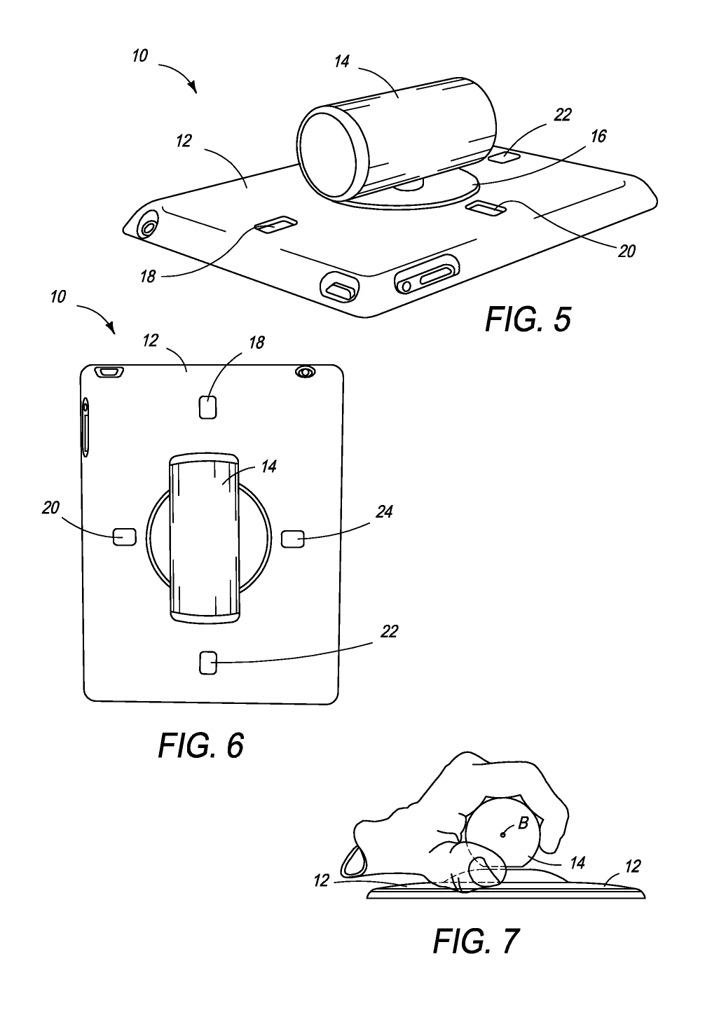

For example, the holder assembly may include a case and one or more handle connectors, as shown in FIGS. 2-5. The case may enclose and/or cover any suitable portions of the personal electronic device. For example, the case may at least partially cover a back portion, side portions, and a perimeter of a front portion of the personal electronic device. Alternatively, the case may at least partially cover a back portion and two or more corners of the personal electronic device. Additionally, or alternatively, the case may at least partially cover a back portion, two or more side portions, and a front portion of the personal electronic device.

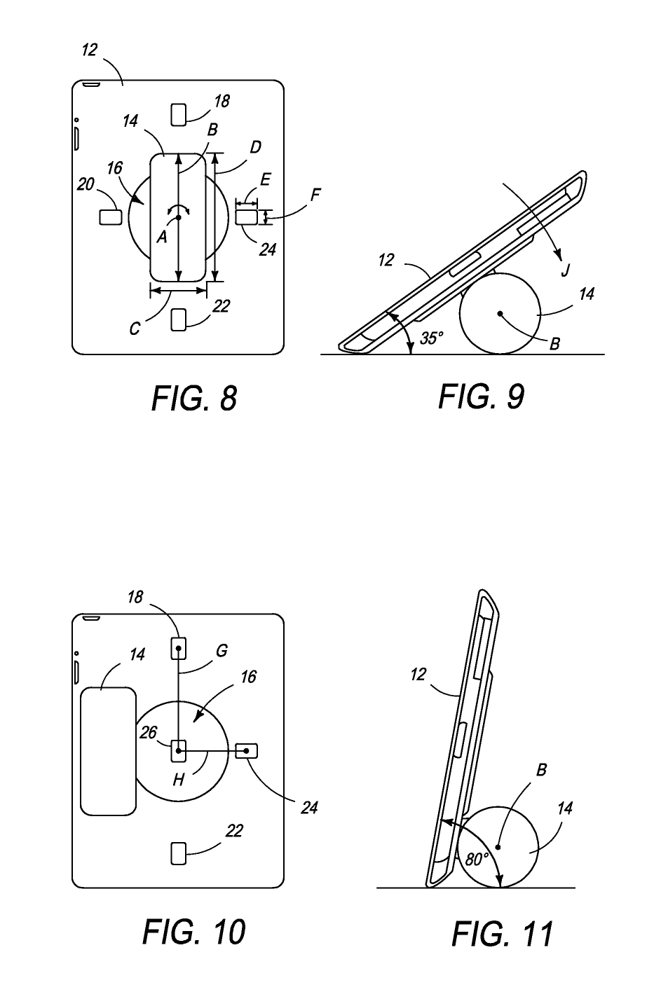

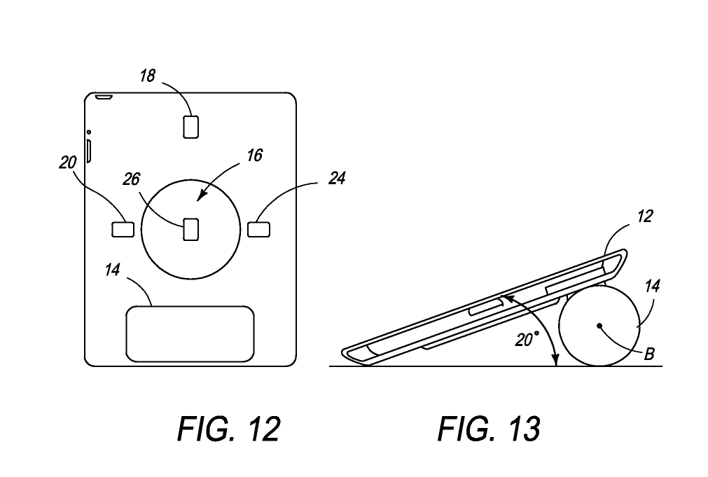

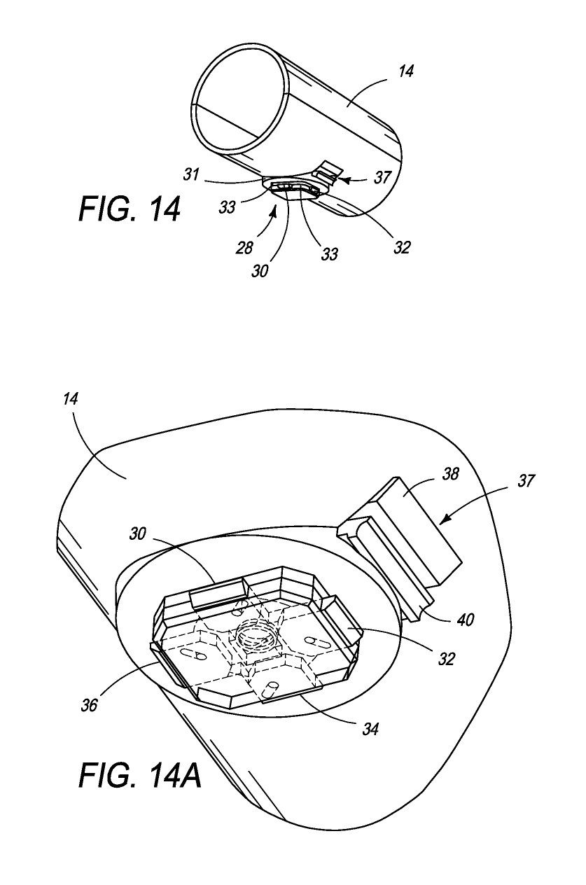

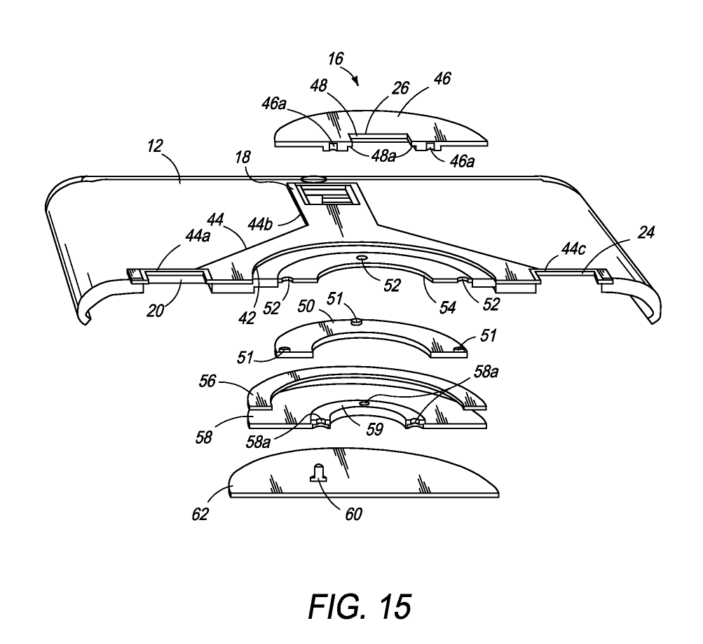

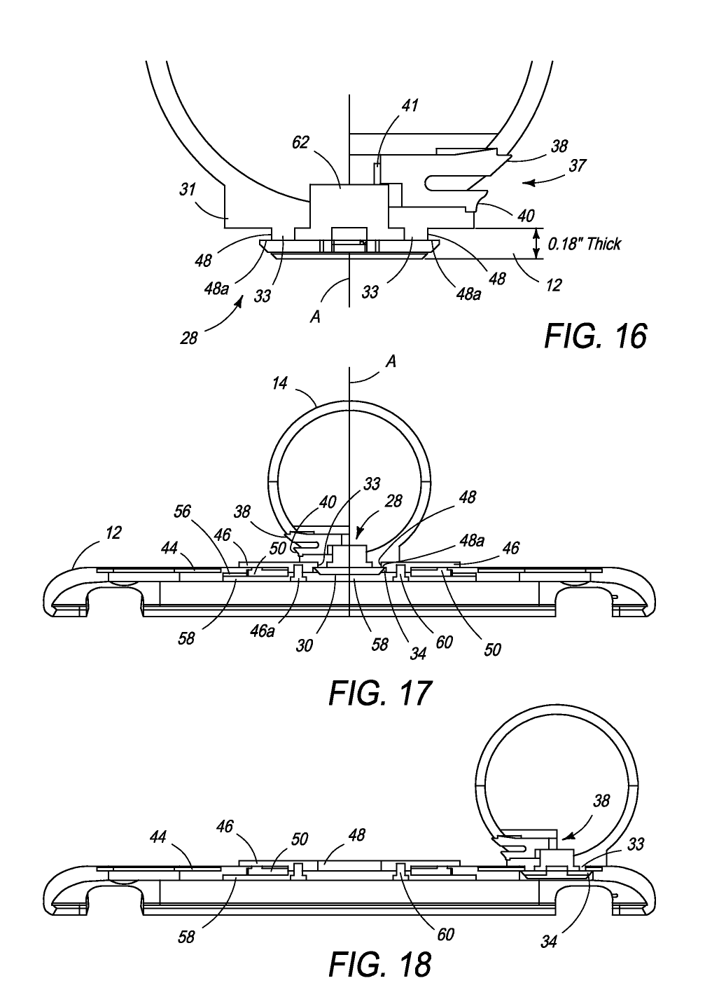

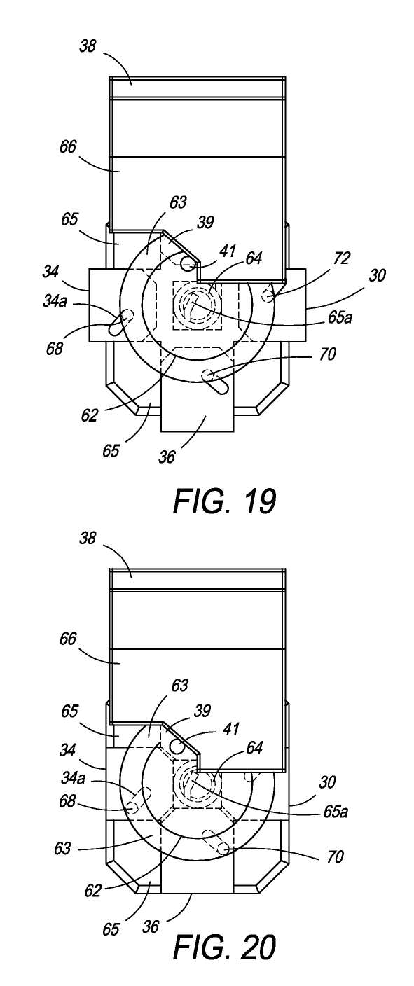

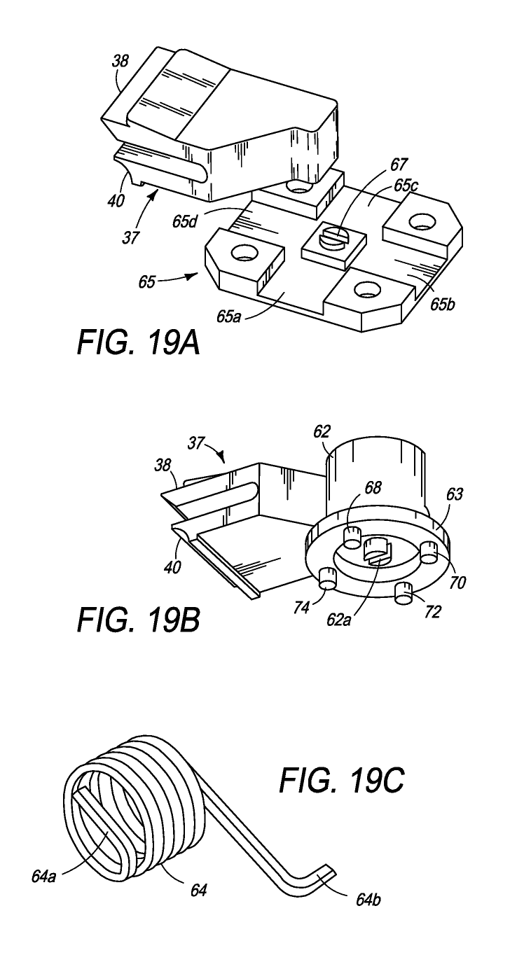

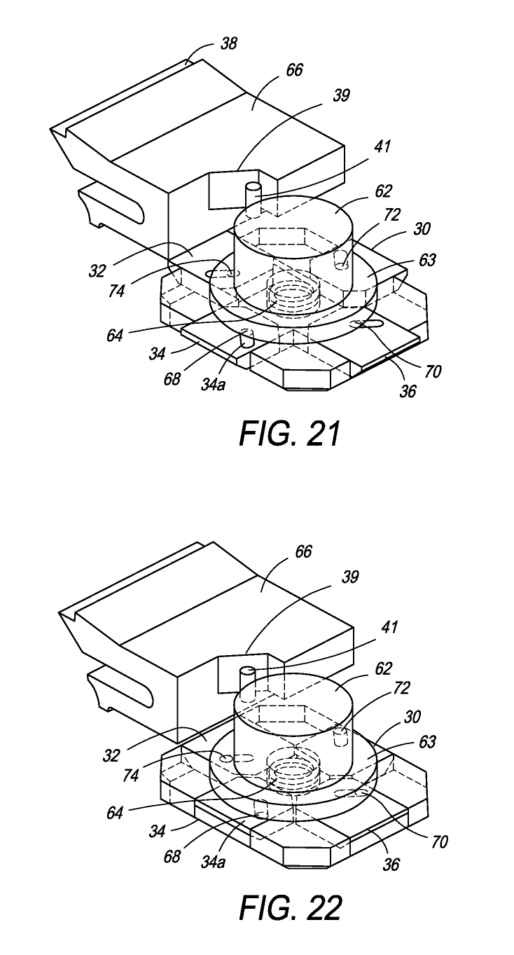

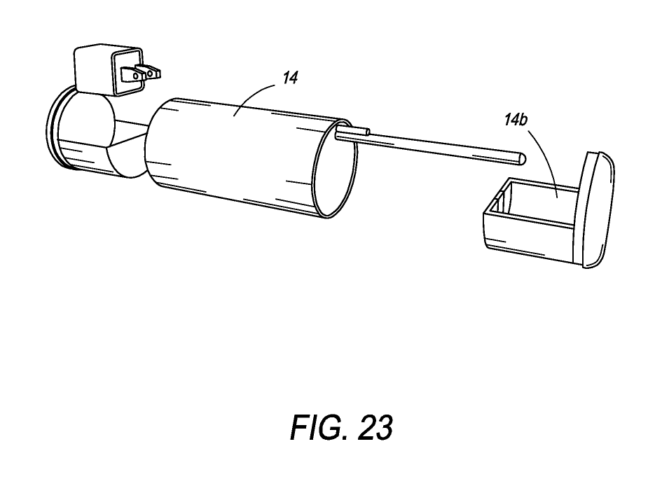

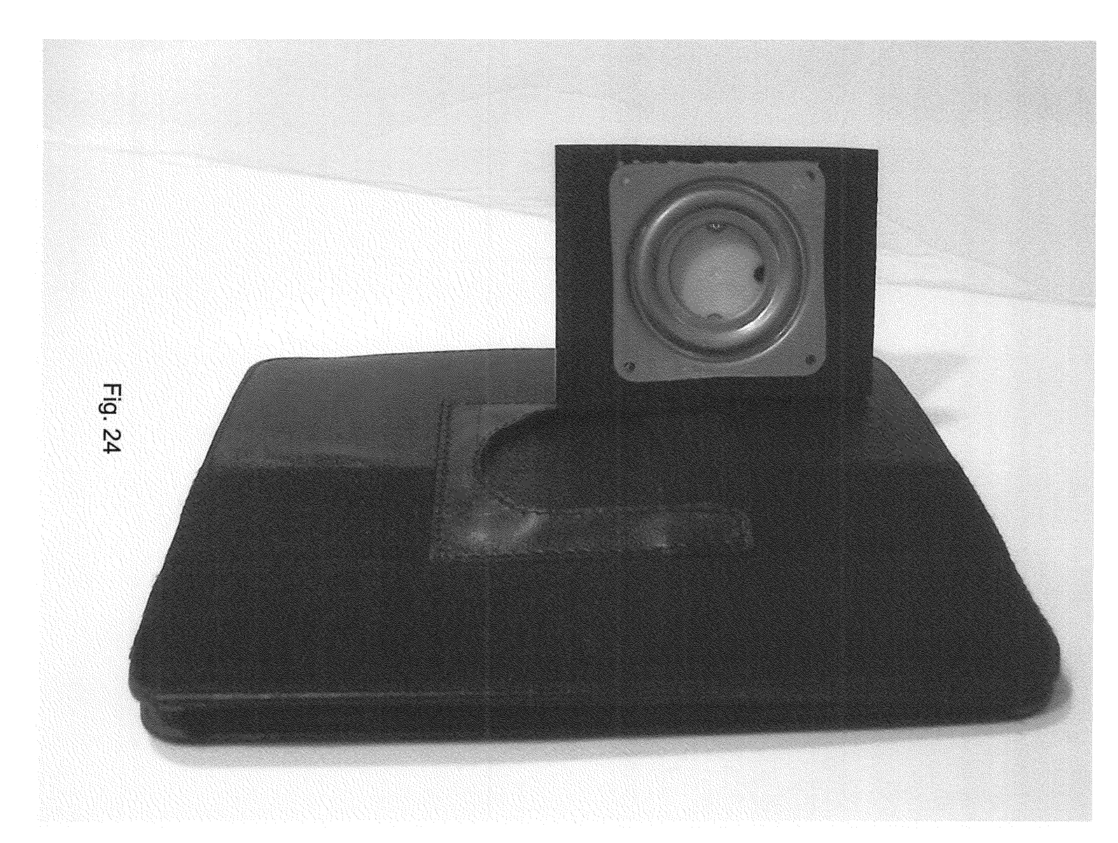

The handle connector may permanently or removably attach the handle assembly to the holder assembly. That connector may include any suitable structure configured to receive and/or connect to the handle assembly. For example, the handle connector may include a sleeve configured to receive the handle assembly. The sleeve may be mounted to the case and be any suitable shape(s), such as a C-shaped sleeve shown in FIGS. 6-24. Alternatively, the handle connector may include one or more apertures and/or protuberances configured to interact with apertures and/or protuberances of the handle assembly. For example, the handle connector may include three apertures configured to receive three prongs from the handle assembly.

The holder assembly may include any suitable number of handle connectors, which may allow a user to connect the handle at various locations. For example, a handle connector may be positioned in a center part of the back portion of the case, and a lower part of the back portion of the case. A user may then be able to select where to attach the handle depending on user preference and/or other factors. In some embodiments, the handle connector may include one or more slots or channels that are configured to receive the handle assembly. For example, the channel(s) may be configured such that one or more parts of the handle assembly may be slid into and/or along the channel(s).

The holder assembly may be configured such that a personal electronic device would fit snugly or loosely into the holder assembly. The case and handle connector(s) may be made of any suitable materials. For example, the case and/or handle connector(s) may be made of one or more of metal, leather, fabric, rubber, wood, and/or plastic materials. The handle connector(s) may include the same or different materials from the case.

Although the holder assembly is shown to include a case and one or more handle connectors, the holder assembly may additionally, or alternatively, include any suitable structure configured to attach to and/or support one or more portions of the personal electronic device. For example, the holder assembly may include one or more clamps that are configured to attach and/or support one or more portions of the personal electronic device. The clamps may be attached and/or mounted to any suitable portions of the case, such as one or more ends and/or corners of the case.

The clamps may be made of any suitable materials, such as one or more of metal, leather, fabric, rubber, and/or plastic materials, and may be the same or different materials from the case and/or handle connector(s). For example, the case may be made of one or more leather materials, while the clamps may be made of one or more rubber materials shaped to grasp or hug one or more portions of the personal electronic device. The clamps may be adjustable to allow the holder assembly to support personal electronic devices of different sizes. The holder assembly may additionally, or alternatively, include one or more bias elements to bias the clamps toward a retracting position.

The holder assembly may additionally, or alternatively, include one or more covers configured to at least partially enclose or cover at least a front portion of the personal electronic device. The cover may be permanently or removably attached to the case by any suitable fasteners, such as stitching, hook-and-loop closure material, etc. Although the holder assembly is shown to attach to and/or support a single personal electronic device, the holder assembly may additionally, or alternatively, be configured to attach to and/or support two or more personal electronic devices. For example, the holder assembly may be configured to support two personal electronic devices side by side. The holder assembly may additionally, or alternatively include other suitable structure configured to attach to and/or support one or more portions of the personal electronic device.

The handle assembly may include any suitable structure configured to be grasped by a user of the personal electronic device and/or be permanently or removably attached to the holder assembly. For example, the handle assembly may include a base, a handle, and one or more holder connector(s). The base may include any suitable structure configured to support one or more other components of the handle assembly.

The handle may be attached to the base and have any suitable shape(s) configured to be grasped by a user. The handle may, for example, have spherical, cubical, rectangular, cylindrical, conical, pyramidal shape(s). The handle may have shape(s) with curvilinear lines, rectilinear lines, and/or any suitable combination of curvilinear and rectilinear lines. For example, the handle may have a shape similar to a computer mouse, a door knob, or a hand sander, as shown in FIGS. 6-24. Alternatively, the handle may have a U-shape and/or any suitable shape(s).

The handle may be any suitable combination of size(s) and shape(s) for a user to grip or hold the handle. In some embodiments, the handle may be any suitable size(s) and/or shape(s) to allow any suitable portion(s) of a user's palm to rest on the handle and for the user's one or more fingers to grip that handle. Alternatively, or additionally, the handle may be any suitable size(s) and/or shape(s) to allow a user to hold the handle using a power grip, and/or any other suitable grip. Additionally, or alternatively, the handle may be any suitable size(s) and/or shape(s) to allow a user to hold the handle on any suitable portion(s) of his or her palm with one or more fingers in an extended position.

In some embodiments, the handle may include an opening to store one or more items, such as accessories related to the personal electronic device (e.g., earphones, power cord, etc.), and a cover to enclose or go over that opening The handle also may include one or more depressions, apertures, protuberances, ribs, etc. to provide an ergonomic fit to a user's hand. For example, the handle may include depressions that correspond to where a user may place his or her fingers or fingertips.

The holder connector(s) may be attached to the base and configured to be connected to the holder assembly. For example, the holder connector may include a flange sized to be received in sleeve(s), channel(s), or slot(s) of the holder assembly, as shown in FIGS. 6-24. Alternatively, or additionally, the holder connector may include one or more prongs and/or protuberances configured to connect to corresponding prongs and/or protuberances of the holder assembly. For example, the holder connector may include three prongs that are sized to be received in three apertures of the holder assembly. The prongs may be configured to provide an interference fit (or friction fit) adapted to allow removal while preventing accidental detachment.

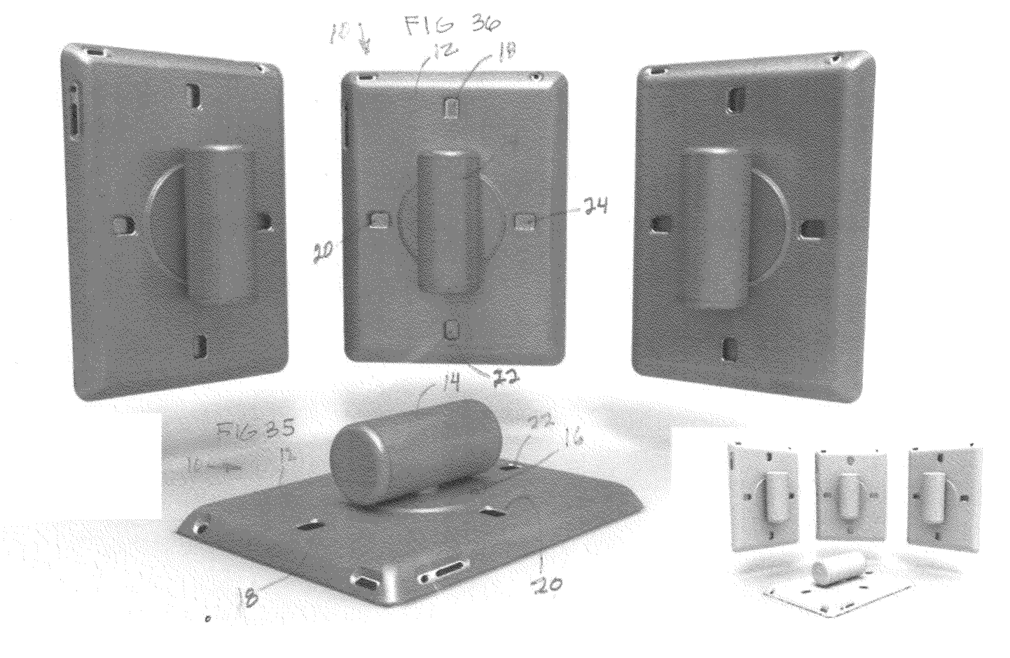

The handle, base, and holder connector(s) may be made of any suitable materials, such as one or more plastic materials, etc. Although the handle assembly is shown to include a base, a handle, and one or more holder connectors, the handle assembly may additionally, or alternatively, include any suitable structure. For example, the handle assembly may additionally, or alternatively, include at least one strap that at least partially wraps around a user's hand. The strap may allow a user to relax his or her grip of the handle without dropping the holder system and/or personal electronic device. The strap may be incorporated with and/or attached to the handle. The strap may be flexible and/or adjustable, or may be fixed or spaced any suitable distance from the handle to allow a user to insert his or her hand between the handle and the strap. Additionally, although the holder system is shown to include separate holder and handle assemblies, the holder and handle assemblies may be a formed single assembly, such as shown in FIG. 34.

Moreover, although the holder system is shown to include a holder assembly and a handle assembly, the holder system may additionally, or alternatively, include one or more other assemblies. For example, the holder system may include a handle locking assembly, which may include any suitable structure configured to secure or lock the handle to the handle assembly. The handle locking assembly may, for example, include one or more handle locking elements.

The handle locking elements may be configured to be moveable between a locking position in which at least a first handle locking element engages at least a second handle locking element to prevent a user from separating the handle assembly from the holder assembly, and an unlocking position in which the first handle locking element is spaced from the second handle locking element to allow a user to separate the handle assembly from the holder assembly.

The handle locking elements may include any suitable structure, such as a strap configured to selectively secure a flange of the handle assembly. Alternatively, or additionally, the handle locking elements may include one or more pins, levers, arms, disks, balls, apertures, slots, etc. One or more parts of the handle locking assembly may be incorporated with the handle and/or holder assemblies. For example, the handle assembly may include one or more pins, while the holder assembly may include one or more apertures sized to receive the pins, or vice-versa.

In some embodiments, the handle locking assembly may include one or more bias elements to bias the handle locking element(s) toward the locking and/or unlocking positions. The bias elements may include one or more coil springs, leaf springs, musical cords, etc. In some embodiments, the handle locking assembly may include at least one activation assembly, which may include any suitable structure configured to allow a user to move one or more of the handle locking elements toward the unlocking and/or locking positions without directly contacting those elements. For example, the activation assembly may include one or more levers, push buttons, cords, gears, etc. At least part of the activation assembly may be manipulable by a user when grasping the handle and/or when holding the case. For example, a push button or lever may be provided on the handle. Although the handle locking assembly is shown to include particular structure, the handle locking assembly may include any suitable structure configured to prevent a user from separating the handle assembly from the holder assembly.

The holder system may additionally, or alternatively, include a motion assembly, which may include any suitable structure configured to allow the handle assembly to move relative to the holder assembly, such as pivot, rotate, and/or slide relative to the holder assembly. The motion assembly may, for example, include one or more bearings (such as one or more lazy susan bearings), pins, turntables, levers, gears, etc.

One or more parts of the motion assembly may be incorporated with the handle and/or holder assemblies. For example, one part of the lazy susan bearing may be mounted on or to the handle, and the other part may be received in a sleeve of the holder assembly. Alternatively, the handle connector of the holder assembly may be pivotably connected to the case, which may allow the handle connector (and the handle) to pivot relative to the case. In some embodiments, the motion assembly may be incorporated into the handle of the handle assembly. For example, a first part of the handle (such as a grip) may be pivotably connected to a second part of the handle (such as a shaft).

The motion assembly may alternatively, or additionally, include one or more channels on the holder assembly configured to receive the handle assembly. The channels may be oriented in any suitable way(s). For example, orthogonal channels may be provided in a “+” or “x” orientation to allow a user to slide the handle assembly relative to the holder assembly. Although the motion assembly is shown to include particular structure, the motion assembly may include any suitable structure configured to allow movement of the handle and holder assemblies relative to each other.

When the holder system includes a motion assembly, that system may additionally include a motion locking assembly, which may include any suitable structure configured to prevent the handle and holder assemblies from moving relative to each other. The motion locking assembly may include similar or different structure from the handle locking assembly. For example, the motion locking assembly may include one or more motion locking elements.

The motion locking elements may be configured to be moveable between a locking position in which at least a first motion locking element engages at least a second motion locking element to prevent a user from moving the holder and handle assemblies relative to each other, and an unlocking position in which the first motion locking element is spaced from the second motion locking element to allow a user to move the holder and handle assemblies relative to each other.

The motion locking elements may include one or more pins, levers, arms, disks, balls, apertures, slots, etc. For example, a first part of the motion assembly may include one or more pins, while a second part of the motion assembly may include one or more apertures sized to receive the pins. In some embodiments, the handle locking assembly may include one or more bias elements to bias the motion locking element(s) toward the locking and/or unlocking positions. The bias elements may include one or more coil springs, leaf springs, musical cords, etc.

In some embodiments, the motion locking assembly may include at least one activation assembly, which may include any suitable structure configured to allow a user to move one or more of the motion locking elements toward the unlocking and/or locking positions without directly contacting those elements. For example, the activation assembly may include one or more levers, push buttons, cords, gears, etc. At least part of the activation assembly may be manipulable by a user when grasping the handle and/or when holding the case. For example, a push button or lever may be provided on the handle, which may be adjacent or spaced from the activation assembly of the handle locking assembly. Although the motion locking assembly is shown to include particular structure, the motion locking assembly may include any suitable structure configured to prevent movement of the handle and holder assemblies relative to each other.

The holder system may additionally, or alternatively, include a stand assembly. The stand assembly may include any suitable structure configured to allow the holder system to support a personal electronic device on a support surface (such as a desk or table) in an inclined position. For example, the stand assembly may include one or more stands that may be moveably connected to the handle and/or holder assemblies. The stands may include rubber grip(s) and/or end(s).

In some embodiments, the one or more stands may be moveably connected to the holder assembly. Alternatively, or additionally, the one or more stands may be moveably connected to the handle assembly. The stand(s) may be configured to allow for both portrait and landscape viewing of the personal electronic device. Alternatively, one or more stands may be provided for portrait viewing, and/or one or more stands may be provided for landscape viewing of the personal electronic device.

In some embodiments, the handle assembly may be configured to perform one or more functions of the stand assembly. For example, the handle may be shaped to allow the holder system to support a personal electronic device on a support surface for portrait and/or landscape viewing. Alternatively, or additionally, the stand assembly may include a hinge mechanism that allows that handle to pivot outward such that the holder system can support a personal electronic device on a support surface for portrait and/or landscape viewing. Although the stand assembly is shown to include particular stands, the stand assembly may include any suitable structure configured to allow the holder system to support a personal electronic device on a support surface in an inclined position.

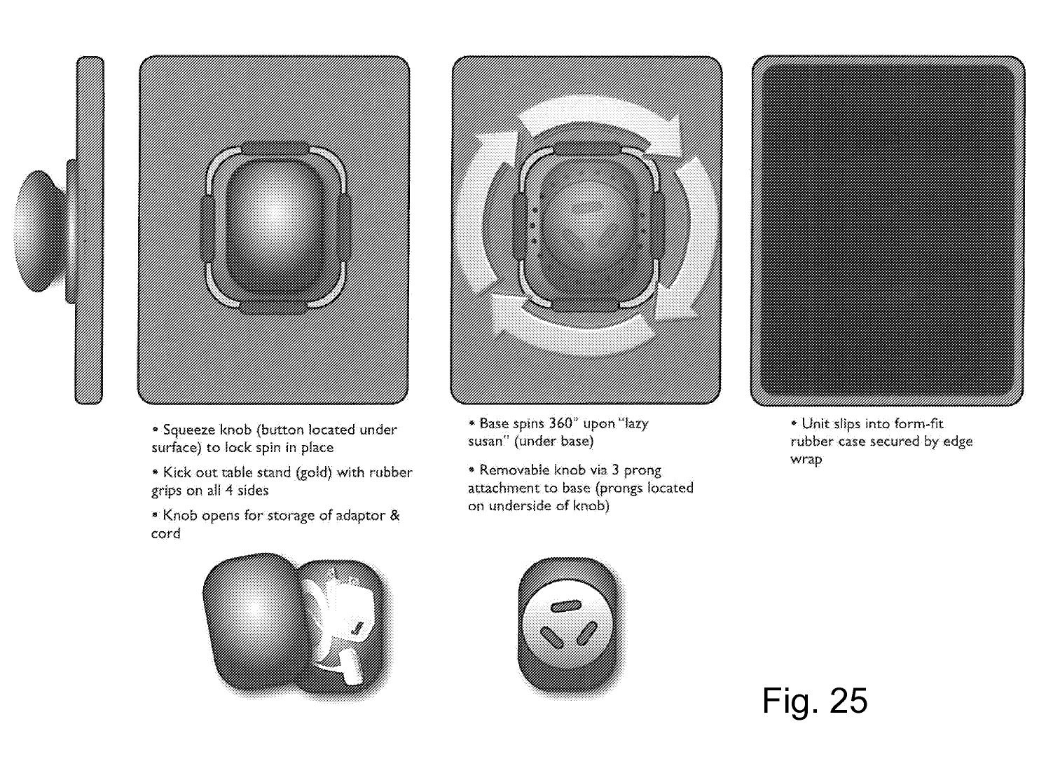

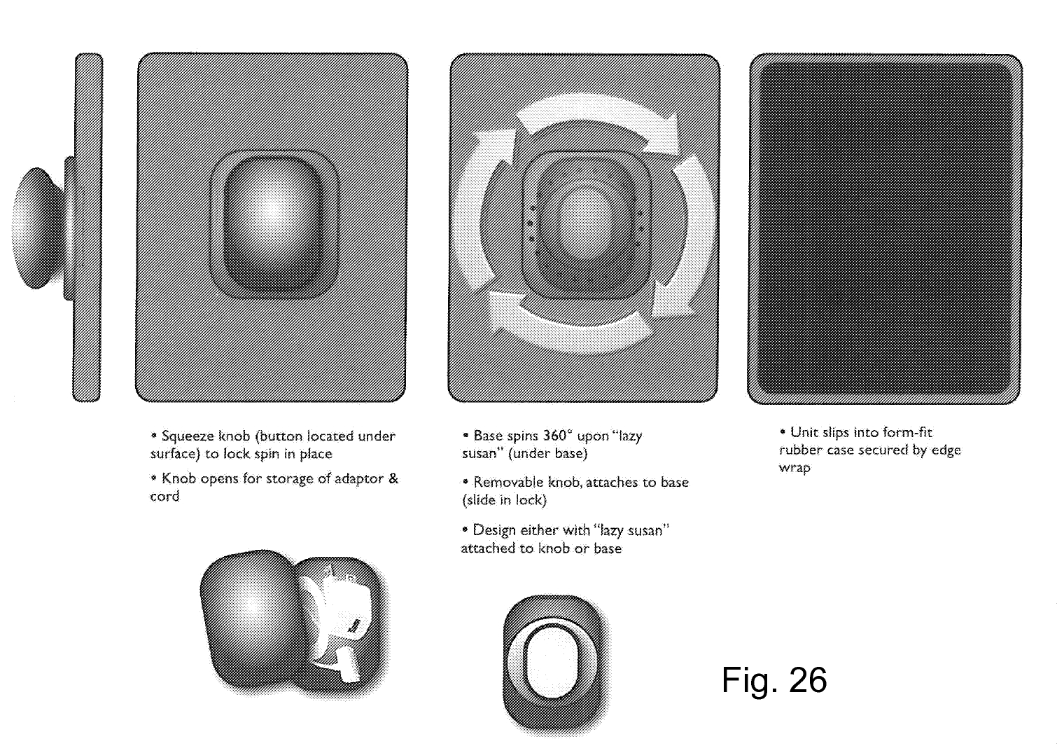

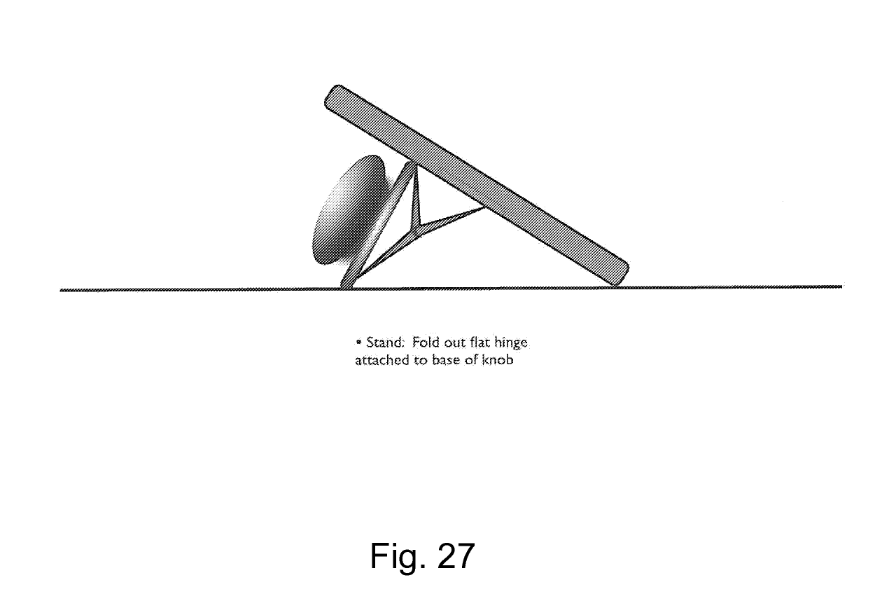

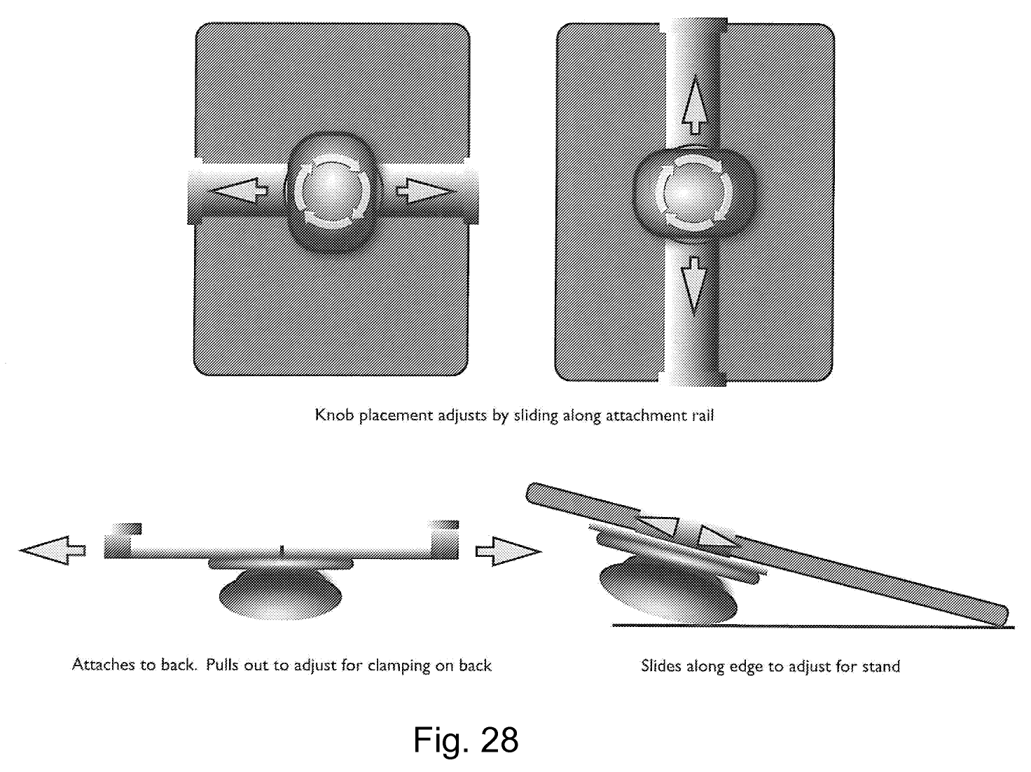

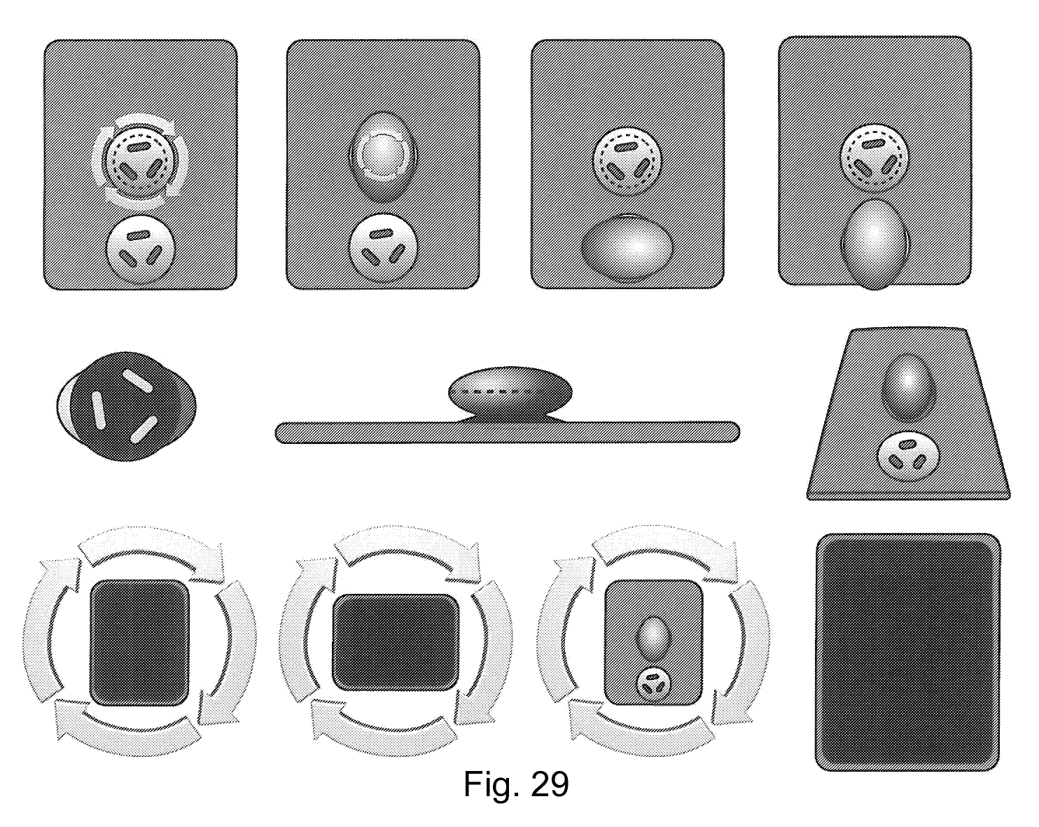

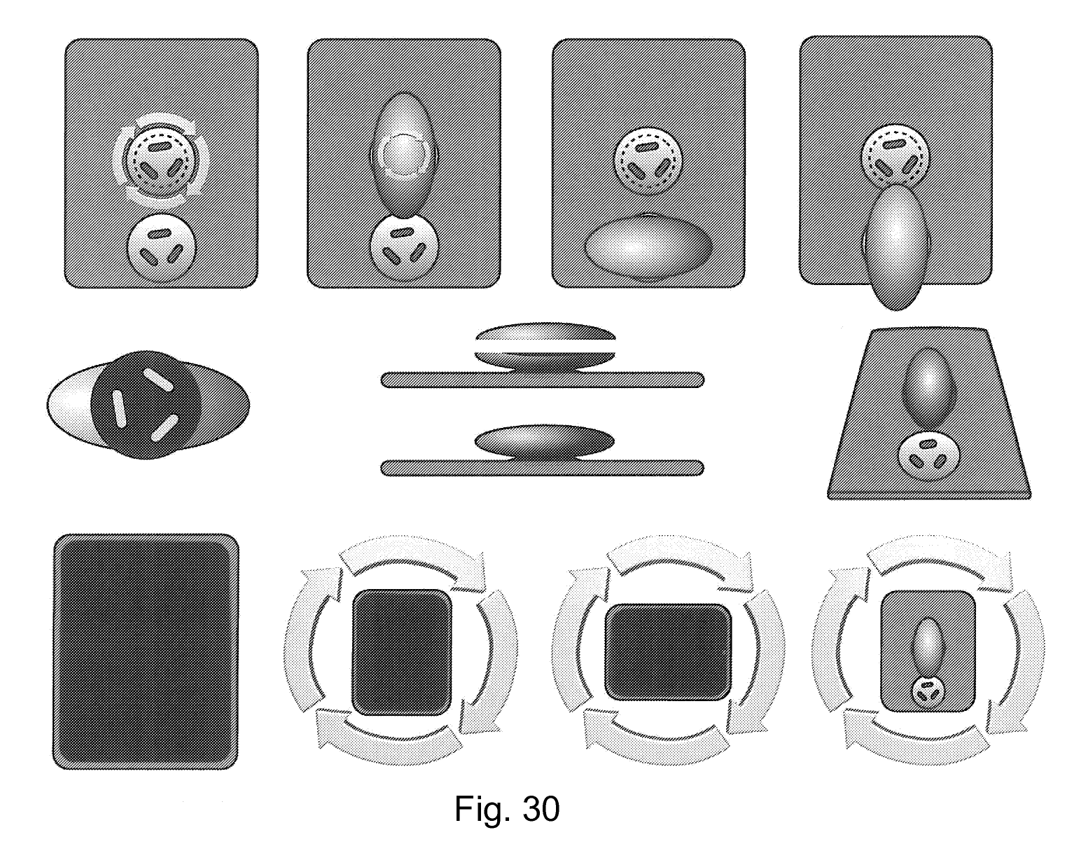

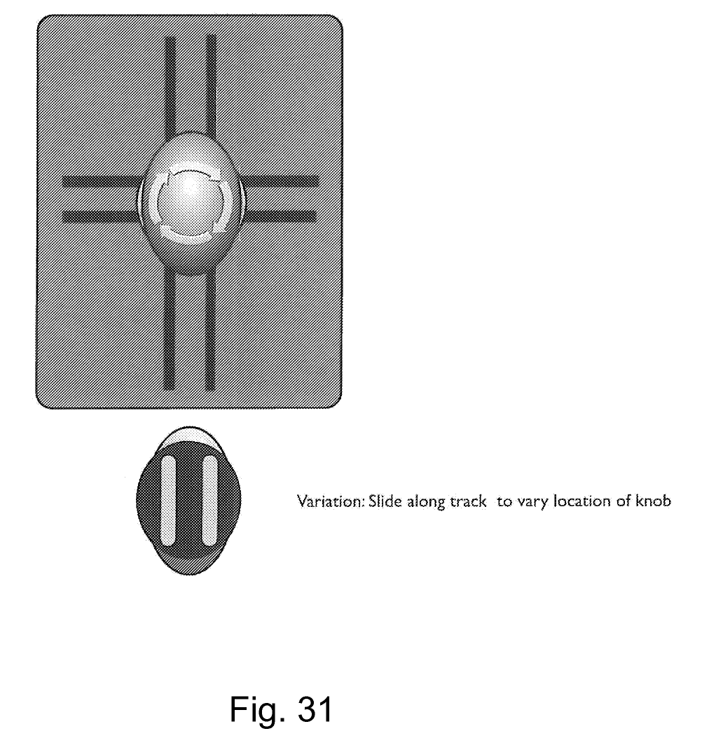

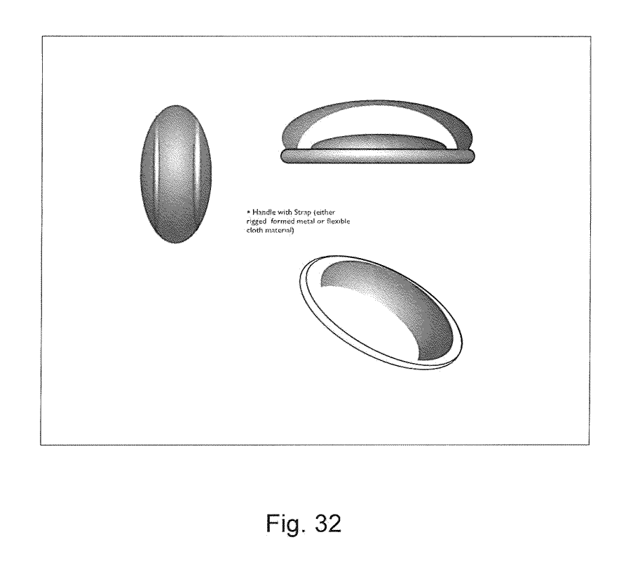

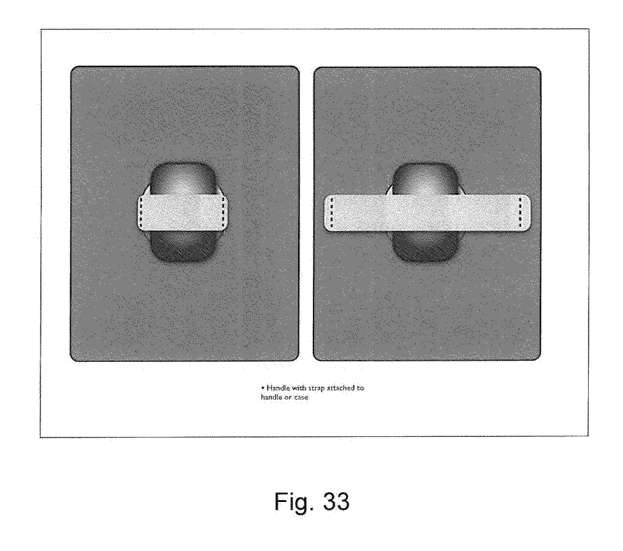

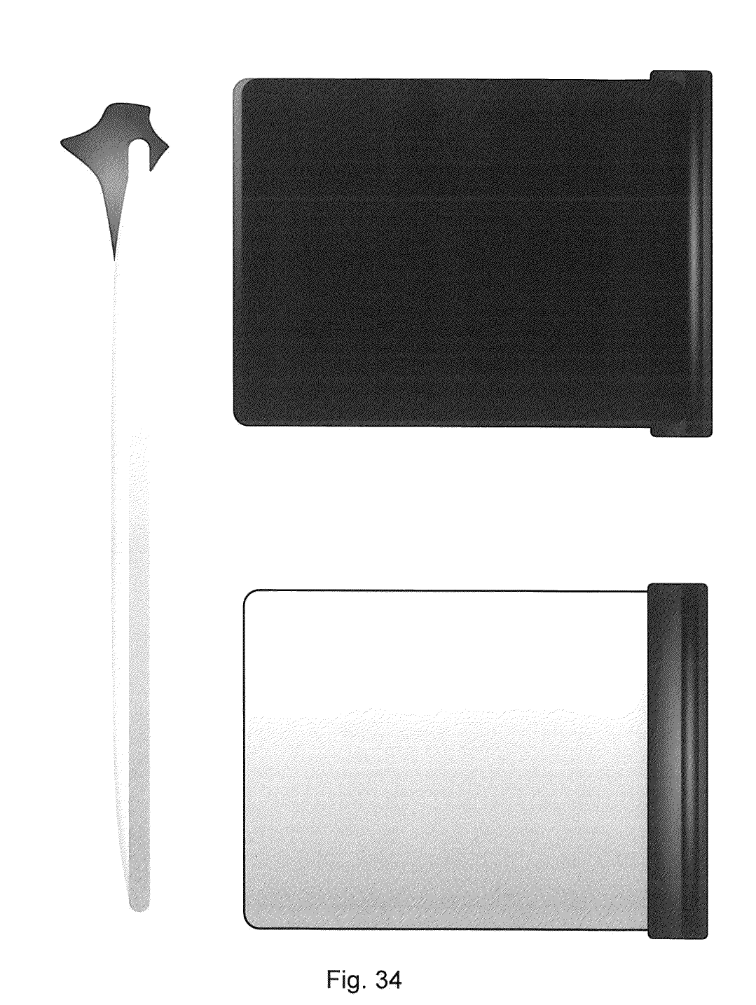

Other examples of holder systems are shown in FIGS. 25-34. Although the holder systems are shown to support one or more personal electronic devices, the holder system may be configured to support other electronic and non-electronic devices, such as a clipboard, a blackboard, an artist palette, a tray, etc.

### Handle/Cover Provided with Releasable Locking Assembly

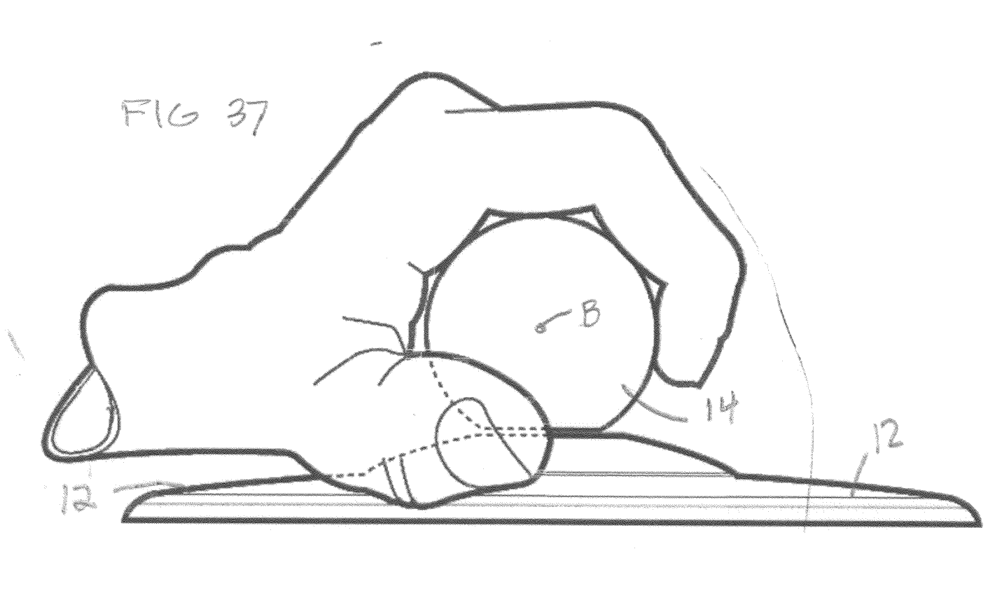

As shown in FIGS. 35 and 36, a handle assembly according to the present invention, indicated at 10, includes a cover 12 and an elongate handle 14 which may be cylindrical. The cover is formed of rubber, polyurethane, or other suitable material as described earlier. The cover is form-fitted for receiving an electronic device, such as an iPad, or other tablet, etc. and is secured by edge wrap. A central rotatable mounting assembly or rotatable mount is generally indicated at 16, and spaced-apart auxiliary mounts are indicated at 18, 20, 22, and 24. The auxiliary mounts are apertures provided in the cover and are aligned with apertures formed in a stabilizing member formed as an insert within the cover, which will be described later.

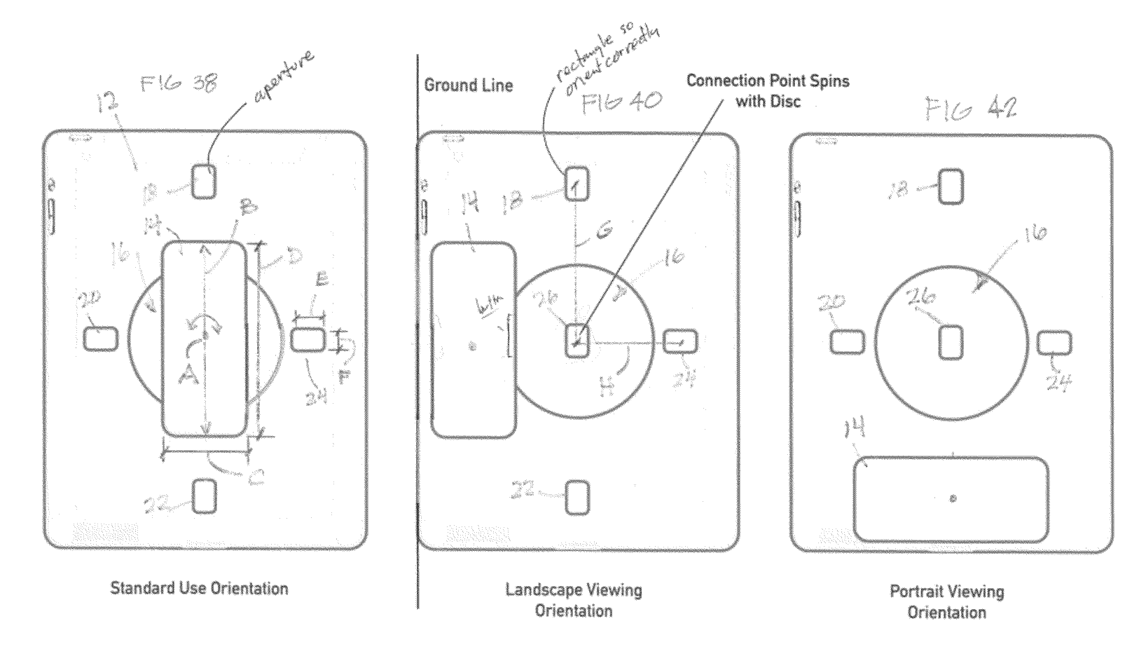

It is to be understood that the handle is dimensioned for being gripped by a person's hand, as shown in FIG. 37, so that the fingers can encircle or wrap around a portion of the handle, with the inside of the fingers and the palm generally facing toward the back of the cover and electronic device. As shown in FIG. 37, a person's thumb may extend in front of the handle, with the four fingers wrapped around the handle itself Of course the handle could be gripped in other ways, i.e., with two hands or with the fingers extended, although the palm usually and most comfortably will face toward the back of the cover. Because the handle is mounted so that it can rotate about an axis generally perpendicular to the plane of the cover and electronic device, a person can grip or hold onto the handle with one hand and rotate the electronic device or tablet with the other hand thereby moving the electronic device as desired, into the portrait or landscape positions. Or the person may type or “point and tap” on the screen of the tablet with the free hand.

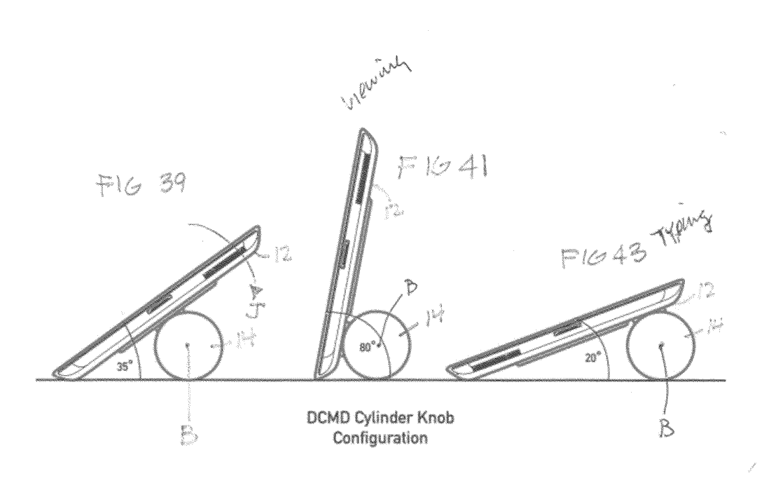

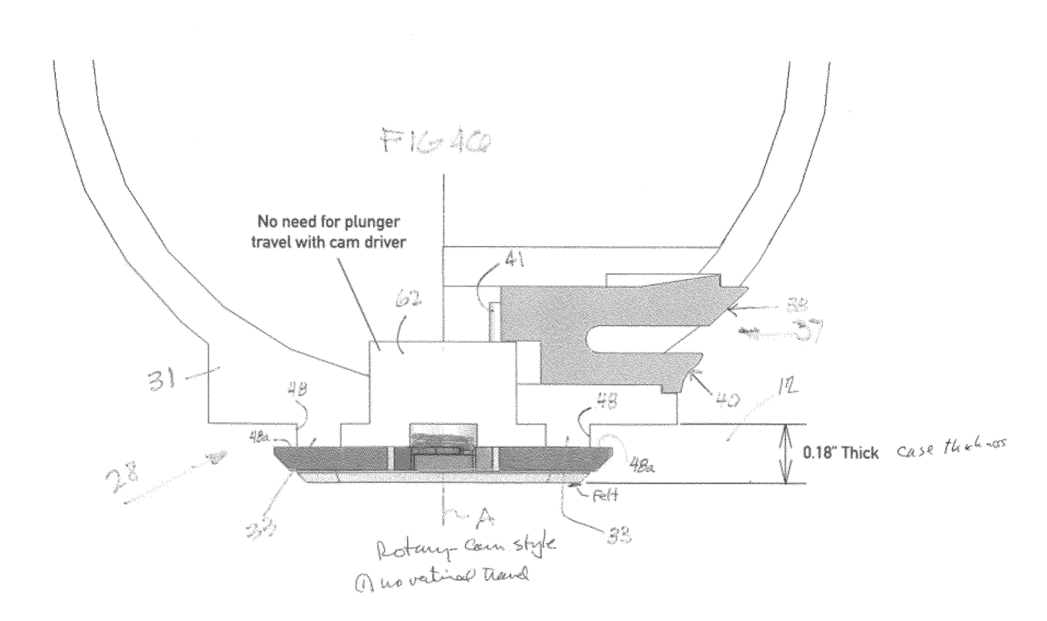

Although a principle function of handle 14 is for gripping by a person, to hold the electronic device, it is also possible to position the handle in the auxiliary mounts, for other purposes. As shown in FIG. 38, which is a top plan view, handle 14 has been mounted in a central mount 26 (see FIG. 42) and may be rotated, relative to cover 12 and the electronic device, about axis A, which is generally perpendicular to the plane of the screen and back of the electronic device. In this position, with the longitudinal axis B positioned essentially parallel to the long axis of the electronic device and cover, the entire assembly may be placed on a flat surface as shown in FIG. 39. With a handle dimensioned with a diameter generally in the range of about 2 inches or thereabouts, the electronic device will be positioned in the “point and tap” orientation, as shown in FIG. 39, which is a side view, taken along the short side of FIG. 38.

In this mode, a person can use the electronic device, where the screen faces upwardly and is at an angle in the range of 35 degrees, relative to the horizontal. That angularity is achieved by the relative dimensioning of an electronic device, such as an iPad, and a handle having an outside diameter generally about 2 inches, indicated at C in FIG. 38. The length of the handle, indicated at D may be in the range of 3-6 inches, although that could be varied. A length of 4½-5 inches has been found acceptable to most. With respect to the auxiliary mounts, they may be provided with an opening having a length E in the range of ¾ inches and a width F of about ⅝ inches.

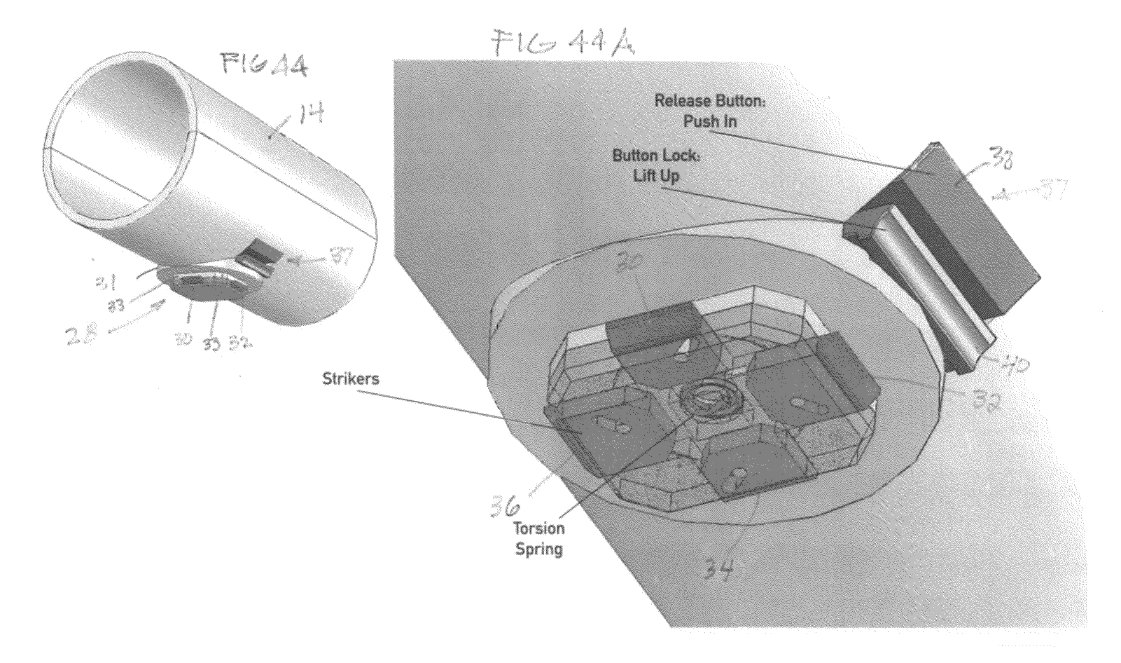

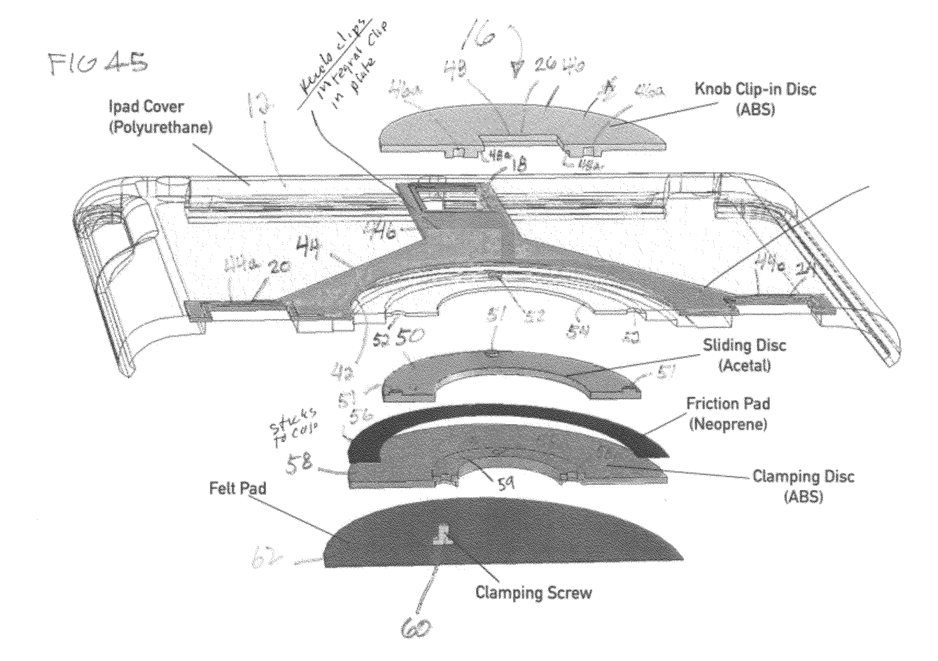

As shown in FIG. 40, the distance G between the center of central mount 26 and the auxiliary mounts, such as 18, may be about 3.6 inches, and with respect to the auxiliary mounts on the long side of the cover may be about 2½ inches, as indicated at H. The release of handle 14 and repositioning in auxiliary mount 20, as shown in FIG. 40, result in the arrangement shown in FIG. 41. When viewed from the side, it can be seen that the screen of the electronic device is placed at an angle roughly about 80 degrees relative to the horizontal for viewing in the landscape orientation. With respect to providing viewing in the portrait orientation, handle 14 may be positioned in auxiliary mount 22, as shown in FIG. 42. If, as shown in FIG. 43, the portrait viewing orientation is arranged as shown, this is also a configuration best adapted for typing.

With handle 14 mounted as shown in FIG. 38, in the “point and tap” orientation as shown in FIG. 39, it can be appreciated that the cylindrical form of handle 14 permits the electronic device to be tilted, in the direction of arrow J around longitudinal axis B so that the electronic device faces in the opposite direction. Thus, a person operating the electronic device from one side may selectively tilt it toward a person on the other side for viewing. The provision of the auxiliary mounts enables handle 14 to be positioned in a selected auxiliary mount for enabling the electronic device to be positioned in the landscape or portrait viewing orientations, as well as in the “point and tap” and typing orientation as shown in FIG. 43.

### The Releasable Mounting Assembly

As indicated previously, handle 14 is detachable, or releaseably mounted for selective positioning in either the central rotatable mount on cover 12 or one of the auxiliary mounts. This is accomplished by a releasable locking assembly, which takes the form in one embodiment of a cam actuated assembly mounted on handle 14. As shown in FIG. 44, a releasable locking assembly, generally indicated at 28, is provided with a plurality of extendable/retractable “strikers” or locking members 30, 32, 34, and 36, two of which are shown in FIG. 44 and all four being shown in FIG. 44A. An actuator, generally indicated at 37, includes a release button or member 38 and a lock member 40 having an elongate concave surface for receiving the thumb or finger. The actuator includes a cam mechanism, to be explained later, that is operable to release or retract the locking members from their normally extended or locked positions.

As shown in FIG. 44, an extension 31 houses the releasable locking assembly, and a four-sided insert indicated at 33, with champhered edges, is dimensioned to fit within a selected mount, such as central mount 26 and the auxiliary mounts. The insert will engage the sides of central mount 26 so that handle 14 may be rotated relative to the cover and the electronic device in a manner to be described.

Before the details of the actuation of locking members 30-36 are described, attention is directed to FIG. 45 which shows, in an exploded view, the central rotatable mount assembly generally indicated at 16. As mentioned previously, the rotatable mount detachably or releaseably receives locking assembly 28 provided on handle 14, and enables selective rotation either clockwise or counterclockwise of handle 14 relative to cover 12. FIG. 45 shows components of central mount 16, cut in half along one of the axes of the cover and in an exploded view. First, it will be noted that there is a central aperture 42 provided in cover 12. A relatively thin, rigid member or insert 44 surrounds aperture 42 and has extensions, such as indicated at 44a, 44b, 44d, and one not shown, which surround the auxiliary mounts. Insert member 44 provides structural integrity and also rigidity for receiving locking assembly 28 of handle 14 in a manner to be described.

Rotatable mount 16 includes an upper disk 46 in which a central opening 48 is provided, of generally rectangular configuration having ledges or extensions 48a. Disk 48 is mounted on top of cover 12 and extends over the top of the cover, and its sides, three of which are indicated at 48a, 48b, and 48c, are dimensioned to engage the sides of a sliding disk 50. That disk, which may be formed of Acetal or other suitable material, is provided with pins or projections 51 which align with apertures such as indicated at 52 for mounting against the bottom of cover 12 adjacent to interior circular opening or bore 54.

A friction pad, which can be made of Neoprene, or other suitable material, is indicated at 56 and is inserted between clamping disk 58 and sliding disk 50. This assembly is held together by a plurality of clamping screws, only one of which is indicated at 60, inserted through apertures 58a in the clamping disk and secured to threaded bores 46a in disk 46. A boss 59 is provided on clamping disk 58, and fits inside the inner diameter of sliding disk 50 when assembled. A felt pad is indicated at 62 and provides a cushion for this construction against a back of the electronic device. The rotatable components include disk 46 interconnected to clamping disk 58. When it is desired to mount handle 14 in central opening 48 of the rotatable assembly, or one of the apertures of the auxiliary mounts, it is necessary first to retract locking members 30-36.

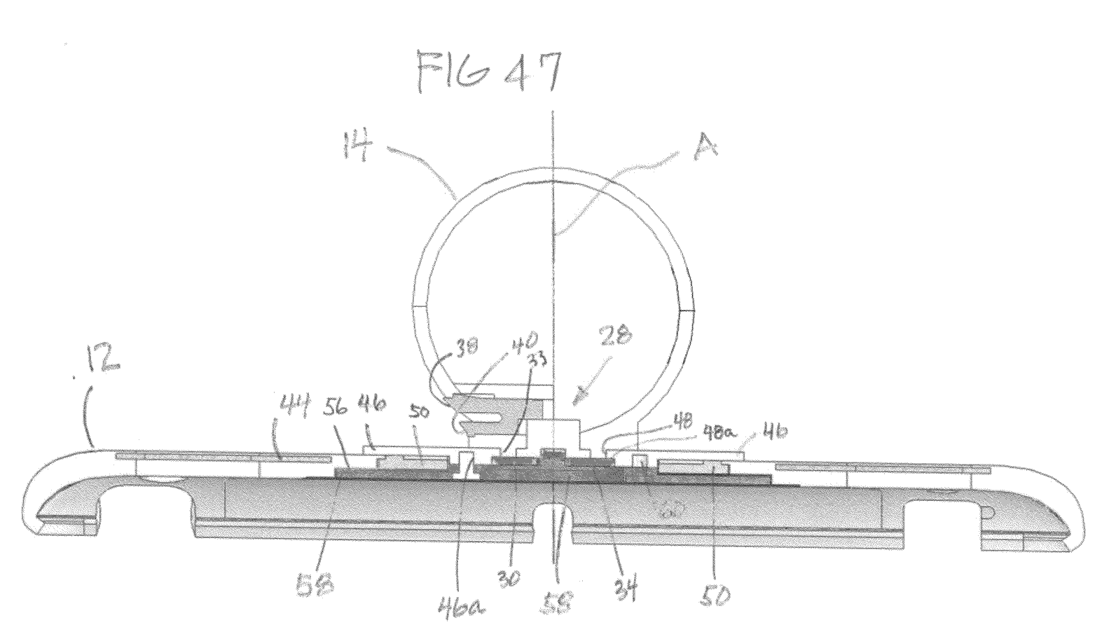

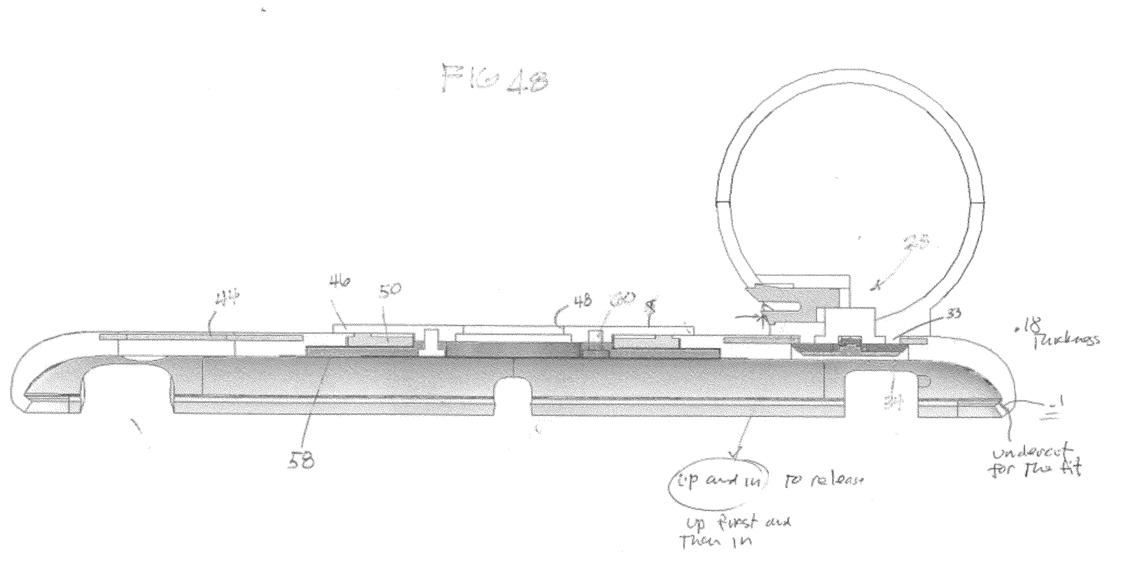

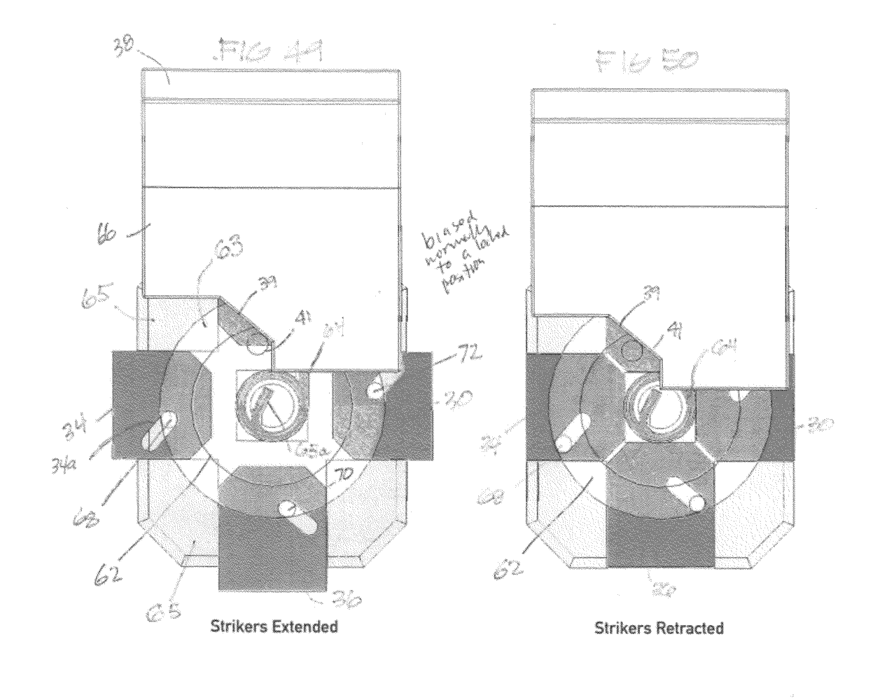

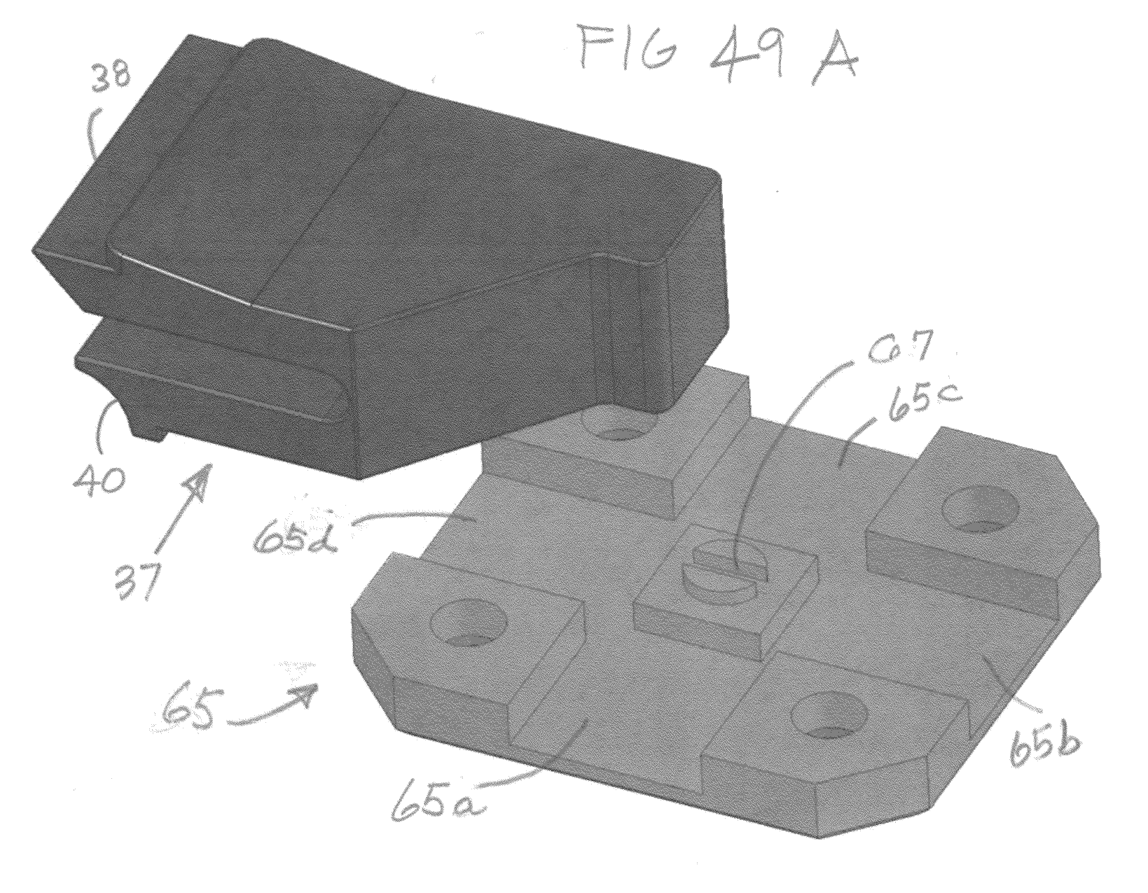

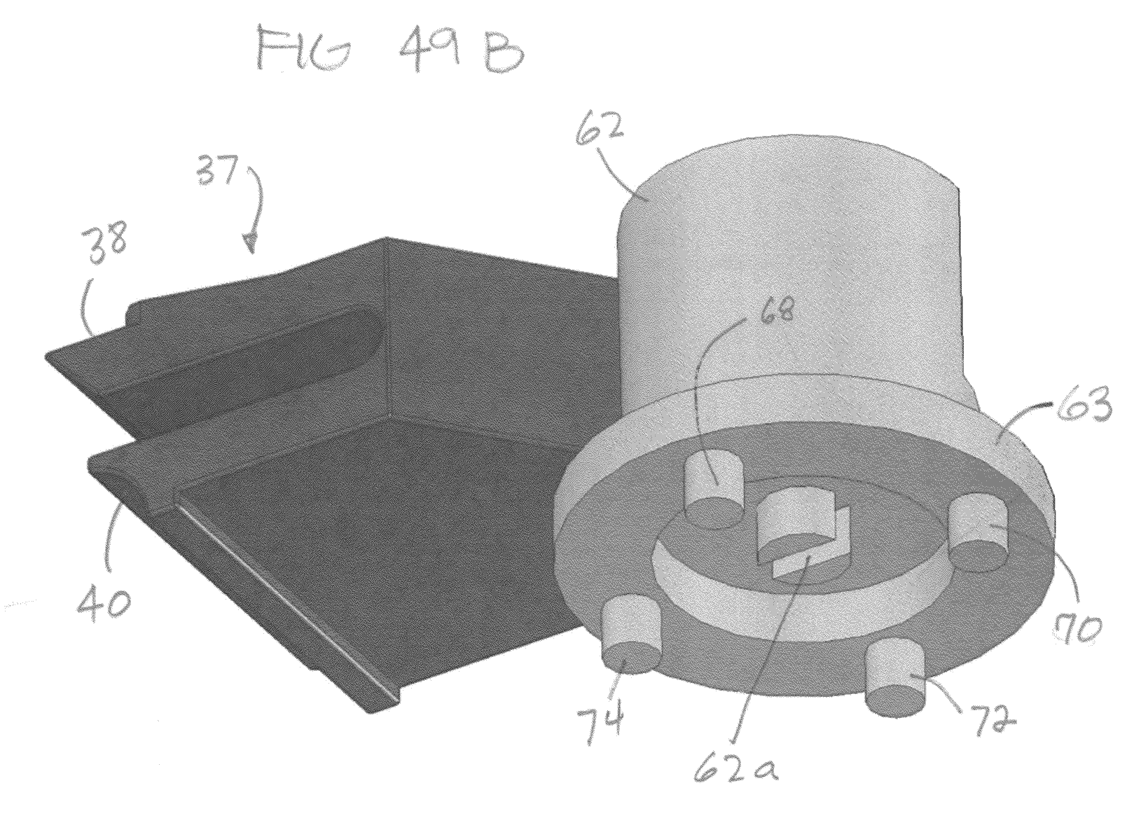

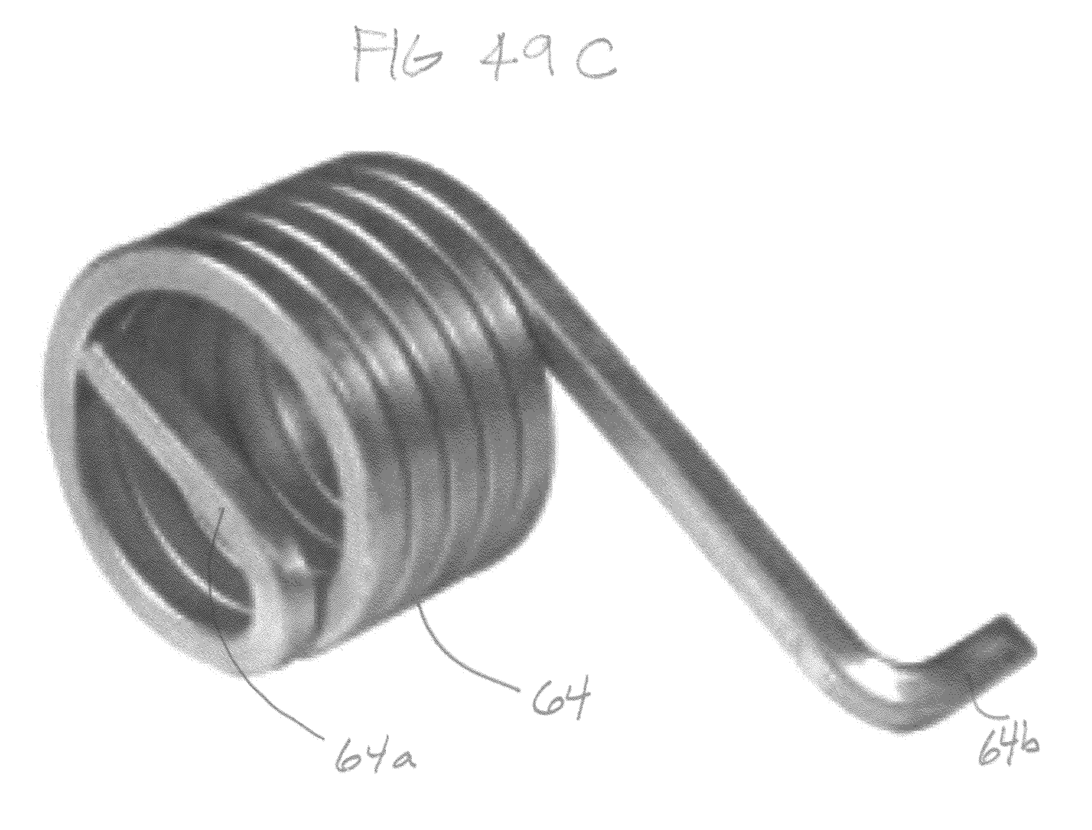

As shown in FIG. 46, the locking members are then extended so that they extend under ledges 48a of central opening 48. This is shown not only in FIG. 46 but also in the assembled cross sectional view of FIG. 47. As shown, locking assembly 28 has been actuated so that its locking members, such as 30, 34 have been extended. In this configuration, handle 14 can rotate about axis A. When it is desired to remove handle 14 from central mount 26, it is necessary to retract locking members 30-36. This is done by pressing against release button 38 and pressing slightly upwardly against the concave surface of lock member 40. What this does, as shown in FIGS. 49 and 50, is to push or slide inclined cam surface 39 against pin 41, which functions as a cam follower extending upwardly from cylindrical member 62.

Normally, locking members 30-36 are extended, by virtue of the action of torsion spring 64. The spring, as shown in FIGS. 49 and 50, is mounted in a base 65 and held in a slot 65a (see the broken-away view of FIG. 49A). The other end of torsion spring 64 is inserted in a slot 62a provided on a lower surface of cylindrical element 62, as shown in the broken-away view of FIG. 49B. As shown in the isolated view of FIG. 49C, spring 64 is configured with a first end 64a dimensioned for being held in slot 65a of base 65. A second end 64b bent from a straightened portion 64c, is dimensioned for being held in slot 62a. The spring normally urges cylindrical member 62 in the clockwise direction, as viewed in FIG. 49, urging release member 38 and lock member 40 outwardly. Mounted on an annular rim 63 of cylindrical element 62 are a plurality of pins 68, 70, 72, and 74 (see FIG. 49B also). These pins are positioned at the inner position in associated inclined channels, such as channel 34a formed in locking member 34. As shown in FIG. 50, when force is applied to release member 38 and lock member 40, against the force of torsion spring 64, cam surface 39 presses and slides against pin 41 of cylindrical member 62 thereby to rotate the cylindrical member.

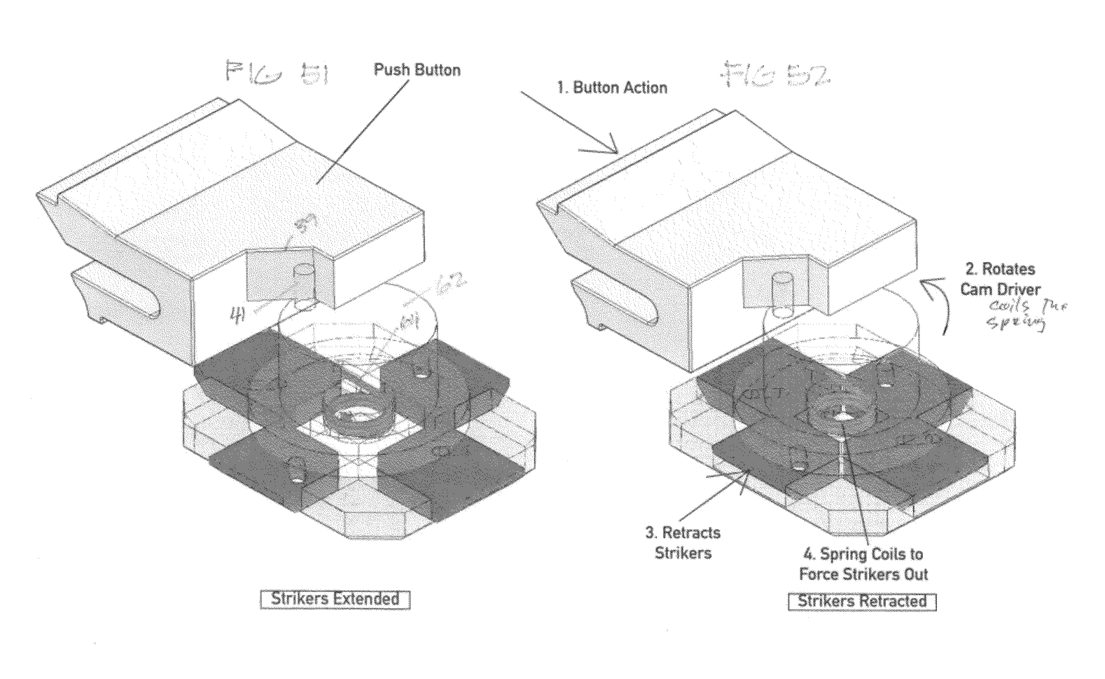

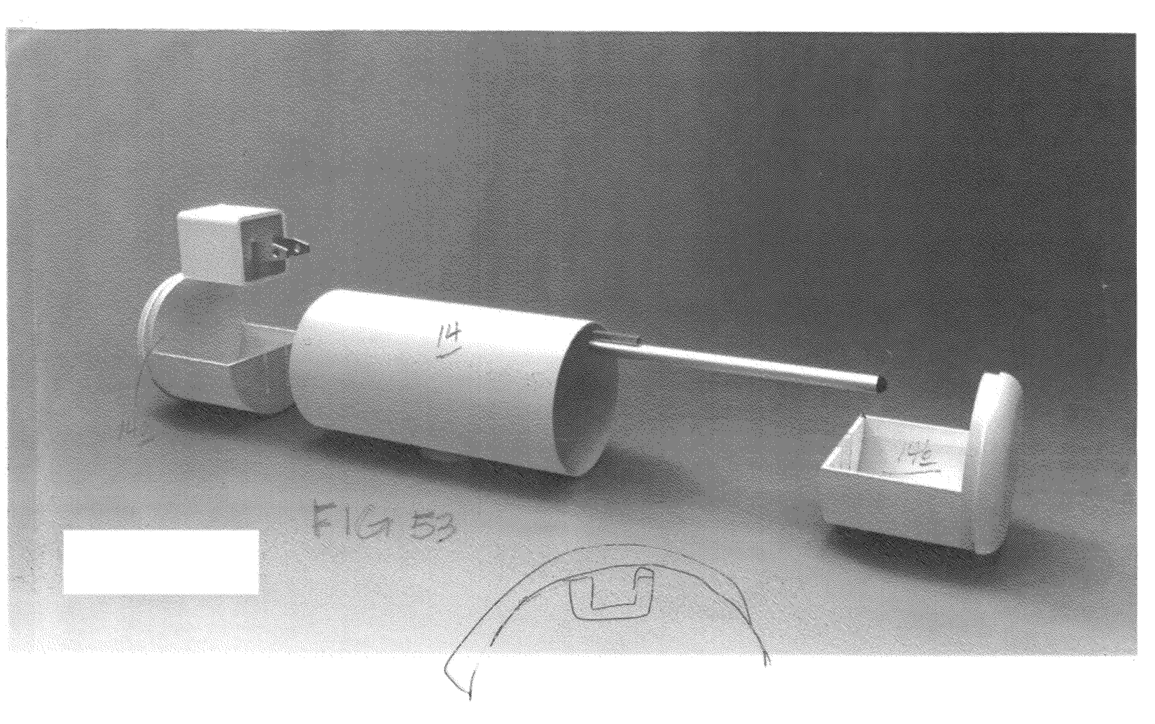

As the cylindrical member rotates, pins 68, 70, 72, and 74 travel in a circular path, and thereby draw or pull in an associated locking member because of the inclined channels, such as channel 34a. Each of locking members 30-36 are axially pulled toward the torsion spring, inasmuch as they are slidably mounted in associated guides, such as indicated at 65a, 65b, 65c, and 65d, as shown in FIG. 49A. Now, the handle may be removed from either the central rotatable mount or one of the auxiliary mounts, as the case may be. This action is further shown in FIGS. 51 and 52, in perspective. These drawings show how torsion spring 64 normally extends locking members 30-36 outwardly. When release button 38 and lock member 40 are actuated, so as to be pushed inwardly and move cam surface 39 so it slides past pin 41, locking members 30-36 are moved inwardly.

As shown in FIG. 53, handle member 14 may be provided with opposed cap trays 14a, and 14b, which may be longitudinally moved from their closed positions outwardly so as to provide an area internal of handle 14 for storage of a stylus, charger cord, etc. Alternatively, threaded end caps may be provided at one or both ends of the handle in order to open it up so that items can be stored.

The disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where any claim recites “a” or “a first” element or the equivalent thereof, such claim should be understood to include incorporation of one or more such elements, neither requiring nor excluding two or more such elements.

Inventions embodied in various combinations and subcombinations of features, functions, elements, and/or properties may be claimed through presentation of new claims in a related application. Such new claims, whether they are directed to a different invention or directed to the same invention, whether different, broader, narrower or equal in scope to the original claims, are also regarded as included within the subject matter of the inventions of the present disclosure.

We claim:

1. An assembly for facilitating holding an electronic device, such as a tablet, or the like comprising:
a cover for detachably receiving and holding the electronic device;
a handle mounted on the cover and rotatable about an axis generally perpendicular to the plane of the back of the electronic device.

2. The assembly of claim 1 wherein the handle is configured to be gripped by one hand with the palm generally facing toward the back of the electronic device.

3. The assembly of claim 2 wherein the handle is dimensioned within an elongate axis generally parallel to the plane of the back of the electronic device when the cover is mounted for receiving the electronic device.

4. The assembly of claim 3 wherein the handle is generally cylindrical in form, dimensioned with an external diameter generally in the range of about 2 inches, and a length sufficient for being gripped by all the fingers.

5. The assembly of claim 1 further including a releasable locking assembly mounted to the handle, operable for selectively extending and retracting locking members to the cover.
